(19) United States
(12) Patent Application Publication
(10) Pub. No.: US 2025/0266674 A1
(43) Pub. Date: Aug. 21, 2025

(54) POWER MONITORING DEVICE

(71) Applicant: HL Mando Corporation, Pyeongtaek-si (KR)

(72) Inventors: Heechul JUNG, Pyeongtaek-si (KR); Kawnseek KIM, Pyeongtaek-si (KR); Hanjun LEE, Pyeongtaek-si (KR)

(21) Appl. No.: 18/965,508

(22) Filed: Dec. 2, 2024

(30) Foreign Application Priority Data
Feb. 16, 2024 (KR) 10-2024-0022453

(51) Int. Cl. H02H 3/08; G01R 15/14; G01R 19/165

(52) U.S. Cl. CPC H02H 3/08; G01R 15/146; G01R 19/16571; G01R 19/16576

(57) ABSTRACT

The present disclosure relates to a device and method for monitoring a power supply unit of a device that supplies power by a battery. A power monitoring device according to the present disclosure includes a current sensor unit including a shunt resistor and an operational (OP) amplifier or a smart field effect transistor (FET) switch including a current sensor and a temperature sensor. Thus, since a capacitor for preventing a short circuit between a thermal fuse and a power supply unit according to the related art can be removed, a ground circuit can be integrated, and a power monitoring circuit can be simplified.

### CROSS-REFERENCE TO RELATED APPLICATION

This application claims priority to and the benefit from Korean Patent Application No. 10-2024-0022453 filed on Feb. 16, 2024, the disclosure of which is incorporated herein by reference in its entirety.

### BACKGROUND

### 1. Field

The present disclosure relates to a power monitoring technology, and more particularly, to a technology for coping with a failure by monitoring a power supply unit.

### 2. Discussion of Related Art

Recently, the spread of electric vehicles that are powered only by electricity has been increasing, and the proportion of electronic devices in internal combustion engine vehicles is also increasing due to the introduction of autonomous driving and driving assistance systems.

In this way, as the use of electricity in vehicles increases, the risk of fire due to a leakage or short circuit of a battery also increases, and thus power management is essential in the vehicles.

In the method of monitoring a power source such as a battery according to the related art, using a thermal fuse and an inverse voltage field effect transistor (FET), when an overcurrent flows, the temperature of a printed circuit board (PCB) increases, a fuse is blown, and thus a current is blocked. Alternatively, the method of monitoring a current using a shunt resistor or the like, monitoring ground open, and performing control thereof when a valve, a motor, a MoC motor, or the like is driven is used.

However, when a power supply unit is monitored and turned off using the thermal fuse or the like in this way, a probability that the PCB or the like is damaged due to the overcurrent or heat is high, and a power monitoring circuit is complicated.

The inventors of the present disclosure have researched to overcome the problem of the power monitoring method according to the related art. After much effort to provide a power monitoring device having a simple structure while protecting load circuits connected to the power source using the shunt resistor, an operational amplifier, or a smart FET, the present disclosure is completed.

### SUMMARY

The present disclosure is directed to providing a power monitoring device capable of protecting a load circuit.

The present disclosure is also directed to providing a power monitoring device in which a protective circuit is implemented with a simple circuit as much as possible without a complex circuit when a power supply unit fails.

Meanwhile, other unspecified purposes of the present disclosure will be additionally considered within the scope that may be easily inferred from the following detailed description and the following effects.

A power monitoring device according to the present disclosure includes a sensor that measures a state of a power supply unit, a switch that connects the power supply unit to a load, and a controller that controls the switch to be turned on or off by a measured value by the sensor.

The sensor may include a current sensor or voltage sensor, and the controller may control the switch to be turned off when a current or voltage measured by the sensor is greater than or equal to a prescribed first reference.

The sensor may include a temperature sensor, and the controller may control the switch to be turned off when a temperature measured by the sensor is greater than or equal to a prescribed second reference.

The power supply unit may include two or more batteries, the sensor may be provided as two or more sensors that measure currents or voltages of the two or more batteries, and the controller may control the switch to connect one of the two or more batteries to the load according to a measured value by the sensor.

A power monitoring device according to another embodiment of the present disclosure includes a power supply unit including a first battery and a second battery, a first sensor that measures a current or voltage from the first battery, a second sensor that measures a current or voltage from the second battery, a switch that selectively connects the first battery or the second battery to a load, and a controller that controls the switch according to a measured value of the first sensor or the second sensor.

The first sensor may comprise a first shunt resistor connected to the first battery in series and a first operational (OP) amplifier of which an input terminal is connected to the first shunt resistor in parallel and an output terminal is connected to the controller, and the second sensor may comprise a second shunt resistor connected to the second battery in series and a second OP amplifier of which an input terminal is connected to the second shunt resistor in parallel and an output terminal is connected to the controller.

The controller may measure a current or voltage from the first or second battery connected to the load by the first sensor or the second sensor and control the switch to be turned off when a measured current or voltage is greater than or equal to a prescribed first reference.

The controller may control the switch to connect the second battery to the load when a current or voltage measured by the first sensor is greater than or equal to a prescribed first reference.

After controlling the switch to connect the second battery to the load, the controller may control the switch to be turned off when a current or voltage measured by the second sensor is greater than or equal to the first reference.

The first sensor may further comprise a first temperature sensor that measures a temperature of the first battery and the second sensor may further comprise a second temperature sensor that measures a temperature of the second battery, and the controller may control the switch to be turned off when a temperature of the first or second battery connected to the load, which is measured by the first sensor or the second sensor, is greater than or equal to a prescribed second reference.

The first sensor may further comprise a first temperature sensor that measures a temperature of the first battery and the second sensor may further comprise a second temperature sensor that measures a temperature of the second battery, and the controller may control the switch to connect the second battery to the load when a temperature measured by the first sensor is greater than or equal to a prescribed second reference.

After controlling the switch to connect the second battery to the load, the controller may control the switch to connect the first battery to the load again when the temperature measured by the first sensor decreases to less than the second reference.

A power monitoring device according to still another embodiment of the present disclosure includes a power supply unit including a first battery and a second battery, a first sensor that measures a current or voltage from the first battery, a second sensor that measures a current or voltage from the second battery, a switch that selectively connects the first battery or the second battery to a load, and a controller that controls the switch according to measured values of the first sensor or the second sensor, wherein the first sensor may include a first smart field effect transistor (FET) switch including a third sensor and a first circuit breaker, and the second sensor may include a second smart FET switch including a fourth sensor and a second circuit breaker.

The first circuit breaker may control the first smart FET switch to be turned off when a current or voltage measured by the third sensor is greater than or equal to a prescribed first reference, and the second circuit breaker may control the second smart FET switch to be turned off when a current or voltage measured by the fourth sensor is greater than or equal to the first reference.

The controller may control the switch to connect the second battery to the load when a current or voltage measured by the third sensor is greater than or equal to a prescribed first reference.

After the controller controls the switch to connect the second battery to the load, the second circuit breaker may control the second smart FET switch to be turned off when a current or voltage measured by the fourth sensor of the second sensor is greater than or equal to the first reference.

The third sensor may include a first temperature sensor that measures a temperature of the first battery and the fourth sensor may include a second temperature sensor that measures a temperature of the second battery, the first circuit breaker may control the first smart FET switch to be turned off when a temperature measured by the third senor is greater than or equal to a prescribed second reference, and the second circuit breaker may control the second smart FET switch to be turned off when a temperature measured by the fourth sensor is greater than or equal to the second reference.

The third sensor may include a third temperature sensor configured to measure a temperature of the first battery and the fourth sensor may include a fourth temperature sensor configured to measure a temperature of the second battery, and when a temperature measured by the third sensor is greater than or equal to a prescribed second reference, the first circuit breaker may control the first smart FET switch to be turned off.

When the first circuit breaker controls the first smart FET switch to be turned off, the controller may control the switch to connect the second battery to the load.

After the controller controls the switch to connect the second battery to the load, when the temperature measured by the third sensor decreases to less than the second reference, the first circuit breaker may control the first smart FET switch to be turned on, and the controller may control the switch to connect the first battery to the load.

### BRIEF DESCRIPTION OF THE DRAWINGS

The above and other objects, features and advantages of the present disclosure will become more apparent to those of ordinary skill in the art by describing exemplary embodiments thereof in detail with reference to the accompanying drawings, in which:

FIG. 1 is a schematic circuit diagram of a power monitoring device according to an exemplary embodiment of the present disclosure;

FIG. 2 is a schematic circuit diagram of a power monitoring device according to another exemplary embodiment of the present disclosure;

FIG. 3 is a schematic circuit diagram of a power monitoring device according to still another exemplary embodiment of the present disclosure; and

FIG. 4 is a schematic structural diagram of a smart field effect transistor (FET) of a power monitoring device according to yet another exemplary embodiment of the present disclosure.

The accompanying drawings are exemplified as reference for understanding the technical spirit of the present disclosure, and the scope of the present disclosure is not limited thereby.

### DETAILED DESCRIPTION

The purposes, means, and effects of the present disclosure will become clearer through the following detailed description related to the accompanying drawings, and accordingly, those skilled in the art to which the present disclosure pertains will be easily implement the technical spirit of the present disclosure. Further, in the description of the present disclosure, when it is determined that the detailed description of widely known technologies related to the present disclosure may make the subject matter of the present disclosure unnecessarily unclear, the detailed description will be omitted.

Terms used in the specification are intended to describe embodiments and are not intended to limit the present disclosure. In the specification, a singular form also includes a plural form unless specifically described in a phrase in some cases. In the specification, terms such as “include,” “be provided with,” “provide,” and “have” do not exclude the presence or addition of one or more other components other than the described components.

In the specification, terms such as “or” and “at least one” may represent one of words listed together or a combination of two or more thereof. For example, “A or B” and “at least one of A and B” may include only one of A or B or may include both A and B.

In the specification, in a description following “for example,” presented information such as cited characteristics, cited variables, or cite values may not exactly coincide, and various embodiments of the present disclosure should not be limited by effects such as deformations including an allowable error, a measurement error, a limit of measurement accuracy, and other commonly known factors.

In the specification, when it is described that a first component is “connected” or “accessed” to a second component, it should be understood that the first component is directly connected or accessed to the second component or a third component may be present therebetween. On the other hand, when it is described that the first component is “directly connected to” or “directly accessed to” the second component, it should be understood that the third component is not present therebetween.

In the specification, when it is described that a first component is provided “on” or “in contact with” a second component, the first component may be in direct contact with or connected to the second component or a third component may be present therebetween. On the other hand, it should be understood that, when it is described that a first component is provided “directly on” or “in direct contact with” a second component, a third component is not present therebetween. Other expressions that describe a relationship between components, such as “between” or “directly between,” may be interpreted similarly.

In the specification, although the terms “first,” “second,” and the like may be used to describe various components, the components should not be limited by the terms. Further, the above terms should be not interpreted to limit a sequence of the components and may be used to distinguish a first component from a second component. For example, a “first component” may be referred to as a “second component”, and similarly, a “second component” may be referred to as a “first component.”

Unless otherwise defined, all the terms used herein may be used as meanings that may be commonly understood by those skilled in the art to which the present disclosure pertains. Further, terms defined in a commonly used dictionary are not interpreted ideally or excessively unless explicitly and specifically defined.

Hereinafter, exemplary embodiments of the present disclosure will be described in detail with reference to the accompanying drawings.

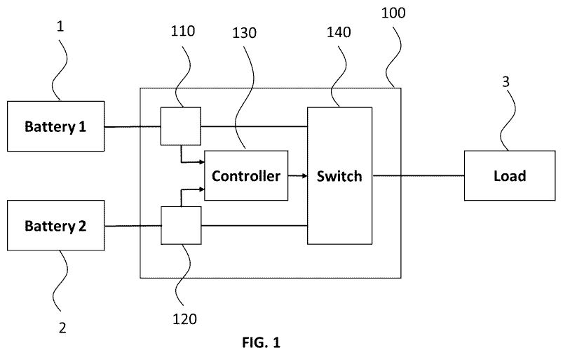

FIG. 1 is a schematic circuit diagram of a power monitoring device according to an exemplary embodiment of the present disclosure.

A power monitoring device 100 according to the present disclosure may include a plurality of sensor units 110 and 120, a controller 130, and a switch unit 140.

The sensor units 110 and 120 are used to measure states of power sources 1 and 2.

To this end, each of the plurality of sensor units 110 and 120 may include a current sensor, a voltage sensor, or a temperature sensor.

The switch unit 140 is used to selectively connect the plurality of power sources 1 and 2 to a load 3. For example, the switch unit 140 may connect or disconnect the power sources 1 and 2 to or from the load 3 and connect only one of the plurality of power sources 1 and 2 to the load 3.

The controller 130 controls the switch unit 140 to be turned on or off according to sensor values measured by the sensor units 110 and 120.

To this end, the controller 130 may include one or more processors and a memory. Information for controlling the power monitoring device 100 and commands for driving the processors may be stored in the memory. The processor may execute commands for operating the controller 130.

The controller 130 may control the switch unit 140 to be turned off when the sensor values for identifying the states of the power sources 1 and 2, which are measured by the sensor units 110 and 120, is in an abnormal state.

For example, when the sensor units 110 and 120 include current sensors or voltage sensors, when currents or voltages of the power sources 1 and 2, which are measured by the sensor units 110 and 120, are greater than or equal to prescribed reference, the switch unit 140 may be blocked to prevent abnormal power from being transferred to the load 3.

Alternatively, when the sensor units 110 and 120 include temperature sensors, when temperatures of the power sources 1 and 2, which are measured by the sensor units 110 and 120, are greater than or equal to prescribed reference, the switch unit 140 may be blocked to prevent abnormal power from being transferred to the load 3.

When the power sources 1 and 2 include the first battery 1 and the second battery 2 and are configured in a backup structure, another battery may supply power instead depending on a situation of each battery.

In this case, the sensor units 110 and 120 may include the first sensor unit 110 and the second sensor unit 120, the first sensor unit 110 may be connected to the first battery 1, and the second sensor unit 120 may be connected to the second battery 2.

For example, the controller 130 may measure the state of the first battery 1 by the first sensor unit 110 and control the switch unit 140 so that instead of the first battery 1, the second battery 2 is connected to the load 3 when the state of the first battery 1 is abnormal, that is, when the voltages or currents are greater than or equal to a prescribed first reference.

The controller 130 may then measure the state of the second battery 2 by the second sensor unit 120 and control the switch unit 140 so that the first battery 1 is connected to the load 3 again when the state of the second battery 2 is changed to an abnormal state. Alternatively, when the state of the second battery 2 is changed to an abnormal state, the controller 130 may control the switch unit 140 to block the connection between the second battery 2 and the load 3. When both the batteries 1 and 2 are blocked, the controller 130 may notify a user of the blocking. To this end, the controller 130 may further include a wired/wireless communication unit (not illustrated).

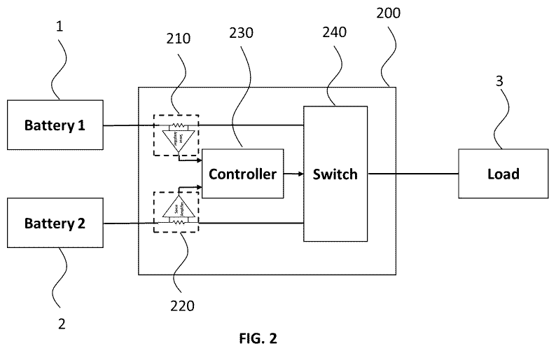

FIG. 2 is a schematic circuit diagram of a power monitoring device according to another exemplary embodiment of the present disclosure.

A power monitoring device 200 according to the present disclosure may include a first sensor unit 210, a second sensor unit 220, a controller 230, and a switch unit 240.

The first sensor unit 210 may be connected to the first battery 1 in series and may include a first shunt resistor and a first operational (OP) amplifier. The first shunt resistor is connected to the first battery 1 in series, an input terminal of the first OP amplifier is connected to the first shunt resistor in parallel, and an output terminal of the first OP amplifier is connected to the controller 230.

The first shunt resistor is used to measure a magnitude of a current flowing from the first battery 1, and the first OP amplifier amplifies a current measured at the first shunt resistor and transmits the amplified current to the controller 230.

The second sensor unit 220 may be connected to the second battery 2 in series and may include a second shunt resistor and a second OP amplifier. The second shunt resistor is connected to the second battery 2 in series, an input terminal of the second OP amplifier is connected to the second shunt resistor in parallel, and an output terminal of the second OP amplifier is connected to the controller 230.

The second shunt resistor is used to measure a magnitude of a current flowing from the second battery 2, and the second OP amplifier amplifies a current measured at the second shunt resistor and transmits the amplified current to the controller 230.

The switch unit 240 is used to selectively connect the plurality of power sources 1 and 2 to the load 3. For example, the switch unit 240 may connect or disconnect the power sources 1 and 2 to or from the load 3 and connect only one of the plurality of power sources 1 and 2 to the load 3.

When the current measured by the first sensor unit 210 or the second sensor unit 220 is greater than or equal to a prescribed first reference, the controller 230 may control the switch unit 240 to block the connection between the power sources 1 and 2 and the load 3.

For example, when the current of the first battery 1, which is measured by the first sensor unit 210, is greater than or equal to the first reference, the controller 230 may control the switch unit 240 to disconnect the first battery 1 from the load 3 and connect the second battery 2 to the load 3 instead of the first battery 1.

After the second battery 2 is connected to the load 3, when the current measured by the second sensor unit 220 is greater than or equal to the first reference, the controller 230 may control the switch unit 240 so as not to connect the second battery 2 to the load 3. When both the batteries 1 and 2 are blocked, the controller 230 may notify the user of the blocking. To this end, the controller 230 may further include a wired/wireless communication unit (not illustrated).

Alternatively, the controller 230 may control the switch unit 240 to reconnect the first battery 1 to the load 3 instead of the second battery 2. Before or after the connection, the controller 230 may identify whether the state of the first battery 1 is normal by the first sensor unit 210 again and determine whether to start or maintain the connection.

The first sensor unit 210 and the second sensor unit 220 may further include a temperature sensor.

In this case, when a temperature measured by the first sensor unit 210 or the second sensor unit 220 is greater than or equal to the first reference, the controller 230 may control the switch unit 240 to block the connection between the first battery 1 or the second battery 2 and the load 3.

When the first battery 1 and the second battery 2 are configured in a backup structure, the controller 230 may control the switch unit 240 to connect the second battery 2 to the load 3 when the temperature of the first battery 1 is measured by the first sensor unit 210 and then the measured temperature is greater than or equal to a prescribed second reference.

After the second battery 2 is connected, when the temperature of the second battery 2, which is measured by the second sensor unit 220, is greater than or equal to the second reference, the controller 230 may control the switch unit 240 to block the connection between the second battery 2 and the load 3.

Alternatively, after the second battery 2 is connected, when the temperature of the first battery 1, which is measured by the first sensor unit 210, returns to a normal value again, that is, when the temperature decreases to less than the second reference, the controller 230 may control the switch unit 240 to connect the first battery 1 to the load 3 again.

In this way, when the sensor unit is configured using the shunt resistor and the OP amplifier, a configuration of the power monitoring device can be simplified.

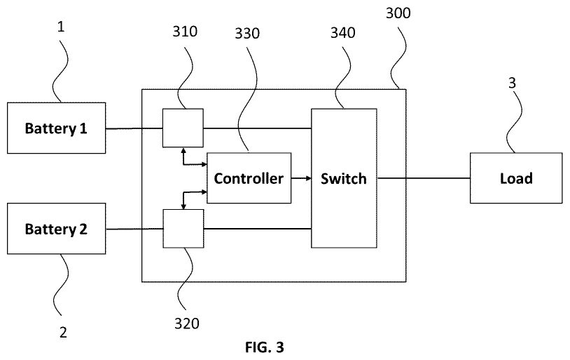

FIG. 3 is a schematic circuit diagram of a power monitoring device according to still another exemplary embodiment of the present disclosure.

A power monitoring device 300 according to the present disclosure may include a first sensor units 310, a second sensor unit 320, a controller 330, and a switch unit 340.

The sensor units 310 and 320 may include smart field effect transistor (FET) switches.

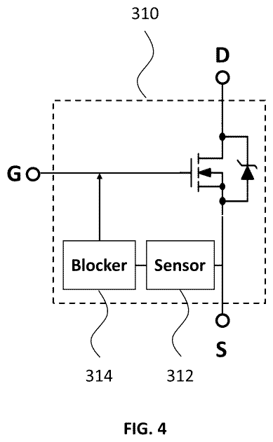

FIG. 4 is a schematic structural diagram of the smart FET switch 310 according to the present disclosure.

The first smart FET switch 310 according to the present disclosure further includes a third sensor unit 312 and a first blocking unit 314 in addition to the configuration of a general FET switch.

A FET switch of the first smart FET switch 310 includes a drain area D, a source area S, and a gate terminal G, and a connection between the drain area and the source area is controlled according to a voltage of the gate terminal.

Thus, the first blocking unit 314 has a structure that may control a connection of the first smart FET switch 310 according to a sensor value measured by the third sensor unit 312.

The first sensor unit 310 may include the first smart FET switch 310 including a third sensor unit 312 and the first blocking unit 314, and the second sensor unit 320 may include the second smart FET switch 320 including a fourth sensor unit and a second blocking unit.

The switch unit 340 is used to selectively connect the plurality of power sources 1 and 2 to the load 3. For example, the switch unit 340 may connect or disconnect the power sources 1 and 2 to or from the load 3 and connect only one of the two power sources 1 and 2 to the load 3.

The controller 330 may control the switch unit 340 based on sensor values measured by the first sensor unit 310 or the second sensor unit 320.

Because the first sensor unit 310 or the second sensor unit 320 includes the blocking unit, power from the first battery 1 or the second battery 2 may be directly blocked.

For example, the first sensor unit 310 may measure the current or voltage of the first battery 1 by the third sensor unit 312 and control the first smart FET switch included in the first sensor unit 310 to be turned off when the measured value is greater than or equal to a prescribed first reference. Likewise, the second sensor unit 320 may measure the current or voltage of the second battery 2 by the fourth sensor unit and control the second smart FET switch included in the second sensor unit 320 to be turned off when the measured value is greater than or equal to the first reference.

Alternatively, when the current or voltage measured by the first sensor unit 310 or the second sensor unit 320 is greater than or equal to the first reference, the controller 330 may control the switch unit 340 to block the connection between the first battery 1 or the second battery 2 and the load 3. Alternatively, the controller 330 may control the gate terminal of the first smart FET switch of the first sensor unit 310 or the first smart FET switch of the second sensor unit 320 so that the first sensor unit 310 or the second sensor unit 320 blocks the connection between the power source and the load 3.

When the first battery 1 and the second battery 2 are configured in a backup structure, the controller 330 may control which battery is connected to the load 3.

For example, when the current or voltage measured by the third sensor unit 312 included in the first sensor unit 310 is greater than or equal to a prescribed first reference, the controller 330 may control the switch unit 340 to connect the second battery 2 instead of the first battery 1 to the load 3. Further, the controller 330 may control the gate terminal of the smart FET switch so that the smart FET switch included in the second sensor unit 320 is turned on.

After the second battery 2 is connected to the load 3, the second sensor unit 320 may measure the current or voltage of the second battery 2, and when the current or voltage is greater than or equal to the first reference, the second blocking unit may control the second smart FET switch included in the second sensor unit 320 to be turned off. Alternatively, instead of the second blocking unit, the controller 330 may control the second smart FET switch included in the second sensor unit 320 to be turned off or control the switch unit 340 to be turned off.

The third sensor unit of the first sensor unit 310 or the fourth sensor unit of the second sensor unit 320 may further include a temperature sensor.

For example, the third sensor unit 312 of the first sensor unit 310 may include a first temperature sensor, and when the temperature measured by the first temperature sensor is greater than or equal to a prescribed second reference, the first blocking unit 314 may block the first smart FET switch of the first sensor unit 310. Alternatively, the controller 330 may control the first smart FET switch of the first sensor unit 310 or control the switch unit 340 to block the connection between the first battery 1 and the load 3.

When the first battery 1 and the second battery 2 are configured in a backup structure, the controller 330 may control the switch unit 340 to disconnect the first battery 1 from the load 3 and connect the second battery 2 to the load 3. The disconnection between the first battery 1 and the load 3 may be performed by the first blocking unit 314 included in the first sensor unit 310.

After the switch unit 340 is controlled to connect the second battery 2 to the load 3, when the temperature measured by the first temperature sensor decreases to less than the second reference again, the first blocking unit 314 may control the first smart FET switch of the first sensor unit 310 to be turned on again. Further, the controller 330 may control the switch unit 340 to connect the first battery 1 to the load 3.

The second blocking unit of the controller 330 or the second sensor unit 320 may control the switch unit 340 or the second smart FET switch of the second sensor unit 320 to disconnect the second battery 2 from the load 3.

In this way, according to the power monitoring device according to the present disclosure, a state of a power source can be measured through a sensor unit including a shunt resistor and an OP amplifier, a temperature sensor can be included to prevent an increase in a temperature due to an overcurrent without including a fuse, and thus a power monitoring circuit can be simplified.

According to the present disclosure, load devices can be protected by monitoring a power supply unit and blocking a high voltage when the power supply unit fails.

Further, the overall circuit size can be decreased by simplifying a power monitoring circuit.

Meanwhile, even in the case of effects not explicitly described herein, effects expected by the technical features of the present disclosure and described in the following specification and potential effects thereof are treated as those described in the specification of the present disclosure.

Specific embodiments have been described in the detailed description of the present disclosure, but it is obvious that various modifications may be made without departing from the scope of the present disclosure. Therefore, the scope of the present disclosure is not limited to the described embodiments and should be determined by the appended claims and equivalents to the appended claims.

What is claimed is:

1. A power monitoring device for connecting a power supply unit to a load, the device comprising:
a sensor configured to measure a state of the power supply unit;
a switch configured to connect the power supply unit to the load; and
a controller configured to control the switch to be turned on or off by a measured value by the sensor.

2. The device of claim 1, wherein the sensor includes a current sensor or voltage sensor, and
the controller is configured to control the switch to be turned off when a current or voltage measured by the sensor is greater than or equal to a prescribed first reference.

3. The device of claim 1, wherein the sensor includes a temperature sensor, and
the controller is configured to control the switch to be turned off when a temperature measured by the sensor is greater than or equal to a prescribed second reference.

4. The device of claim 1, wherein the power supply unit includes two or more batteries,
the sensor is provided as two or more sensors configured to measure currents or voltages of the two or more batteries, and
the controller is configured to control the switch to connect one of the two or more batteries to the load according to a measured value by the sensor.

5. A power monitoring device, the device comprising:
a power supply unit including a first battery and a second battery;
a first sensor configured to measure a current or voltage from the first battery;
a second sensor configured to measure a current or voltage from the second battery;
a switch configured to selectively connect the first battery or the second battery to a load; and
a controller configured to control the switch according to a measured value by the first sensor or the second sensor.

6. The device of claim 5, wherein the first sensor comprises:
a first shunt resistor connected to the first battery in series; and
a first operational (OP) amplifier of which an input terminal is connected to the first shunt resistor in parallel and an output terminal is connected to the controller, and
the second sensor comprises:
a second shunt resistor connected to the second battery in series; and
a second OP amplifier of which an input terminal is connected to the second shunt resistor in parallel and an output terminal is connected to the controller.

7. The device of claim 5, wherein the controller is configured to measure a current or voltage from the first or second battery connected to the load by the first sensor or the second sensor and control the switch to be turned off when a measured current or voltage is greater than or equal to a prescribed first reference.

8. The device of claim 5, wherein the controller is configured to control the switch to connect the second battery to the load when a current or voltage measured by the first sensor is greater than or equal to a prescribed first reference.

9. The device of claim 8, wherein, after controlling the switch to connect the second battery to the load, the controller is further configured to control the switch to be turned off when a current or voltage measured by the second sensor is greater than or equal to the first reference.

10. The device of claim 5, wherein the first sensor further comprises a first temperature sensor configured to measure a temperature of the first battery and the second sensor further comprises a second temperature sensor configured to measure a temperature of the second battery, and
the controller is configured to control the switch to be turned off when a temperature of the first or second battery connected to the load, which is measured by the first sensor or the second sensor, is greater than or equal to a prescribed second reference.

11. The device of claim 5, wherein the first sensor further comprises a first temperature sensor configured to measure a temperature of the first battery and the second sensor further comprises a second temperature sensor configured to measure a temperature of the second battery, and
the controller is configured to control the switch to connect the second battery to the load when a temperature measured by the first sensor is greater than or equal to a prescribed second reference.

12. The device of claim 11, wherein, after controlling the switch to connect the second battery to the load, the controller is further configured to control the switch to connect the first battery to the load again when the temperature measured by the first sensor decreases to less than the second reference.

13. A power monitoring device, the device comprising:
a power supply unit including a first battery and a second battery;
a first sensor configured to measure a current or voltage from the first battery;
a second sensor configured to measure a current or voltage from the second battery;
a switch configured to selectively connect the first battery or the second battery to a load; and
a controller configured to control the switch according to measured values of the first sensor or the second sensor,
wherein the first sensor includes a first smart field effect transistor (FET) switch including a third sensor and a first circuit breaker, and
the second sensor includes a second smart FET switch including a fourth sensor and a second circuit breaker.

14. The device of claim 13, wherein the first circuit breaker is configured to control the first smart FET switch to be turned off when a current or voltage measured by the third sensor is greater than or equal to a prescribed first reference, and
the second circuit breaker is configured to control the second smart FET switch to be turned off when a current or voltage measured by the fourth sensor is greater than or equal to the first reference.

15. The device of claim 13, wherein the controller is configured to control the switch to connect the second battery to the load when a current or voltage measured by the third sensor is greater than or equal to a prescribed first reference.

16. The device of claim 15, wherein, after the controller controls the switch to connect the second battery to the load, the second circuit breaker is further configured to control the second smart FET switch to be turned off when a current or voltage measured by the fourth sensor is greater than or equal to the first reference.

17. The device of claim 13, wherein the third sensor further includes a first temperature sensor configured to measure a temperature of the first battery and the fourth sensor further includes a second temperature sensor configured to measure a temperature of the second battery,
the first circuit breaker is configured to control the first smart FET switch to be turned off when a temperature measured by the first temperature senor is greater than or equal to a prescribed second reference, and
the second circuit breaker is configured to control the second smart FET switch to be turned off when a temperature measured by the second temperature sensor is greater than or equal to the second reference.

18. The device of claim 13, wherein the third sensor further includes a first temperature sensor configured to measure a temperature of the first battery and the fourth sensor further includes a second temperature sensor configured to measure a temperature of the second battery, and
when a temperature measured by the first temperature sensor is greater than or equal to a prescribed second reference, the first circuit breaker is configured to control the first smart FET sensor to be turned off.

19. The device of claim 18, wherein, when the first circuit breaker controls the first smart FET switch to be turned off, the controller is further configured to control the switch to connect the second battery to the load.

20. The device of claim 19, wherein, after the controller controls the switch to connect the second battery to the load, when the temperature measured by the first temperature sensor decreases to less than the second reference, the first circuit breaker controls the first smart FET switch to be turned on, and the controller is configured to control the switch to connect the first battery to the load.
